(19) United States
(12) Patent Application Publication
(10) Pub. No.: US 2026/0032849 A1
(43) Pub. Date: Jan. 29, 2026

(54) ELECTRONIC DEVICE AND AN INSTALLATION ASSEMBLY THEREOF

(71) Applicant: COOLER MASTER TECHNOLOGY INC., Taipei City (TW)

(72) Inventors: YUQING LYU, Hui Zhou City (CN); CHAOFENG ZENG, Hui Zhou City (CN)

(73) Assignee: COOLER MASTER TECHNOLOGY INC., Taipei City (TW)

(21) Appl. No.: 19/265,020

(22) Filed: Jul. 10, 2025

(30) Foreign Application Priority Data
Jul. 29, 2024 (CN) 202421809449.8

(51) Int. Cl. H05K 7/14; H05K 7/18

(52) U.S. Cl. CPC H05K 7/1489; H05K 7/1417; H05K 7/183

(57) ABSTRACT

An installation assembly configured for mounting a motherboard includes a plurality of parallel mounting rods, each having a plurality of first fastening structures arranged along a longitudinal direction. The installation assembly further includes a tray configured to receive the motherboard and a plurality of second fastening structures disposed on the tray and selectively engageable with the first fastening structures. When disengaged from the first fastening structures, the tray is movable along the longitudinal direction of the mounting rods to adjust a positional relationship between the tray and the mounting rods.

### CROSS-REFERENCE TO RELATED APPLICATIONS

This application is a non-provisional and claims priority under 35 U.S.C. § 119 to China Application No. 202421809449.8, filed Jul. 29, 2024, the contents are thereby incorporated by reference in their entirety.

### TECHNICAL FIELD

The present disclosure relates to an electronic device and an installation assembly, and more particularly an electronic device and a tray installation assembly having multiple mounting rods.

### BACKGROUND

In modern society, information technology is developing rapidly, and most of business enterprises utilize servers to facilitate their business operations. Servers are commonly used to store programs, files, and data, thereby enhancing operational efficiency. To enhance the usage of internal space within a server chassis and offer greater flexibility and simplicity in designing the internal layout, trays are frequently mounted within the chassis. These trays support motherboards along with particular electronic components, enabling the centralized and organized placement of these components in designated areas within the chassis.

Conventional trays, however, exhibit constrains regarding installation flexibility and user-friendliness. More specifically, existing trays are typically secured to the chassis using fasteners, necessitating the use of hand tools within the chassis' limited area during installation. This process can be cumbersome and inefficient. Accordingly, there is still a demand in the art for improved tray mounting mechanisms that allow for more flexible and convenient installation within server chassis.

### SUMMARY

The present disclosure is directed to an electronic device and a tray installation assembly that enhances the flexibility and convenience of tray installation within an electronic enclosure, such as a server chassis.

An aspect of the present disclosure provides an electronic device. The electronic device having an installation assembly that includes a plurality of mounting rods, each having a plurality of first fastening structures, the mounting rods being parallel to one another, and the first fastening structures being arranged along longitudinal directions of the mounting rods, respectively, a tray, a plurality of second fastening structures configured to be disposed on the tray and selectively fastened to the first fastening structures, such that when the first and the second fastening structures are disengaged, the tray is movable along a longitudinal direction of the mounting rods to adjust a positional relationship therebetween, and a motherboard detachably mounted to the tray.

In one embodiment, each of the first fastening structures includes a threaded hole, and each of the second fastening structures includes a screw configured to pass through the tray and be selectively threaded into the first fastening structure.

In one embodiment, each of the first fastening structures includes a latch hole, each of the second fastening structures includes a flexible latch member, and one side of the second fastening structure is rotatably mounted to the tray.

In one embodiment, each of the second fastening structures includes a first plate, a second plate, and a third plate, a first side of the first plate being rotatably mounted to the tray, two sides of the second plate on the side being respectively connected to a second side of the first plate and the third plate, thereby forming an assembly slot with the first, second, and third plate collectively.

In one embodiment, the third plate includes an elastic arm portion and a latch protrusion, the latch protrusion being located on the elastic arm portion adjacent to the assembly slot, and the mounting rods being configured to be at least partially received within the assembly slot, thereby allowing the latch protrusion to engage with the first fastening structures.

In one embodiment, the latch protrusion protrudes from the third plate towards the first plate.

In one embodiment, each of the second fastening structures includes a fourth plate, the fourth plate being connected to a side of the third plate opposite the second plate and protruding in a direction away from the latch protrusion.

In one embodiment, the electronic device further comprising a plurality of pivot members, wherein the first side of the first plate is pivotally mounted to the tray via a respective pivot member.

In one embodiment, the electronic device further comprises at least one mounting component removably mounted to at least a portion of the mounting rods.

In one embodiment, a spacing between any two adjacent ones of the first fastening structures is 10 millimeters.

Another aspect of the present disclosure provides an installation assembly configured for mounting a motherboard. The installation assembly includes a plurality of mounting rods, each having a plurality of first fastening structures, the mounting rods being parallel to one another, and the first fastening structures being arranged along longitudinal directions of the mounting rods, respectively, a tray configured to receive the motherboard, and a plurality of second fastening structures configured to be disposed on the tray and selectively fastened to the first fastening structures, allowing the tray to move along a longitudinal direction of the mounting rods to adjust a positional relationship therebetween when the first fastening structures and the second fastening structures are disengaged.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

FIG. 1 is a perspective view of an electronic device in accordance with an embodiment of the present disclosure.

FIG. 2 is an exploded view of the electronic device shown in FIG. 1.

FIG. 3 is a top view of the electronic device shown in FIG. 1.

FIG. 4 is a perspective view of an electronic device in accordance with an embodiment of the present disclosure.

FIG. 5 is a top view of the electronic device shown in FIG. 4.

FIG. 6 is a top view of an electronic device in accordance with an embodiment of the present disclosure.

FIG. 7 is a top view of an electronic device in accordance with an embodiment of the present disclosure.

FIG. 8 is a top view of an electronic device in accordance with an embodiment of the present disclosure.

FIG. 9 is a perspective view of an electronic device in accordance with an embodiment of the present disclosure.

FIG. 10 is a partially enlarged exploded view of the electronic device shown in FIG. 9, with the motherboard omitted.

FIG. 11 is a partially enlarged cross-sectional view of the electronic device shown in FIG. 9, with the motherboard omitted.

FIG. 12 is a partially enlarged perspective view of the electronic device shown in FIG. 9, illustrating a second fastening structure prior to engaging with a mounting rod.

FIG. 13 is a partially enlarged perspective view of the electronic device shown in FIG. 9, illustrating the second fastening structure about to engage with the mounting rod.

FIG. 14 is a partially enlarged side view of the portion shown in FIG. 13.

FIG. 15 is a partially enlarged cross-sectional view taken along line 15-15 of FIG. 14.

FIG. 16 is a partially enlarged perspective view of the electronic device shown in FIG. 9, illustrating the second fastening structure engaged with the mounting rod.

FIG. 17 is a partially enlarged cross-sectional view of the portion shown in FIG. 16.

### DETAILED DESCRIPTION

Various embodiments will be described in detail with reference to the drawings, wherein like reference numerals represent like parts and assemblies throughout the several views. Reference to various embodiments does not limit the scope of the claims attached hereto. Additionally, any examples set forth in this specification are not intended to be limiting and merely set forth some of the many possible embodiments for the appended claims.

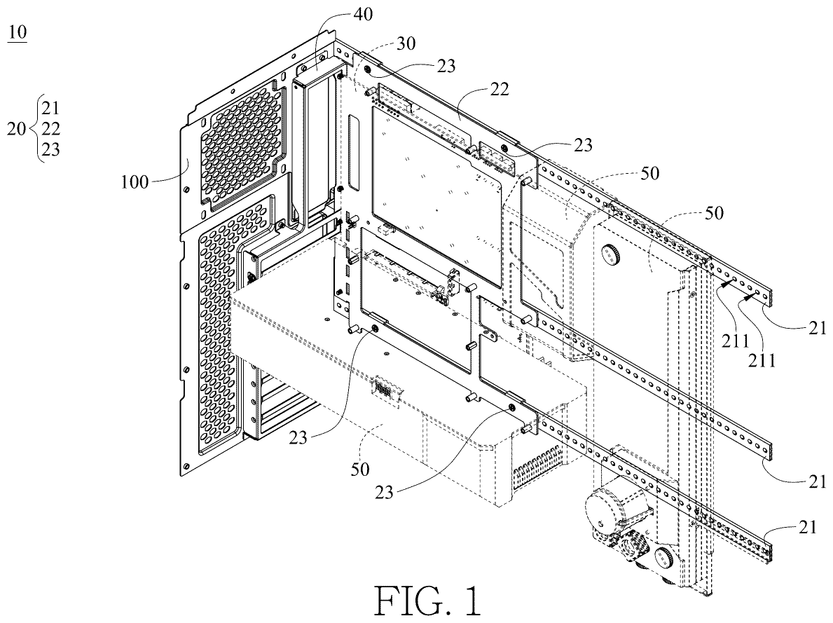

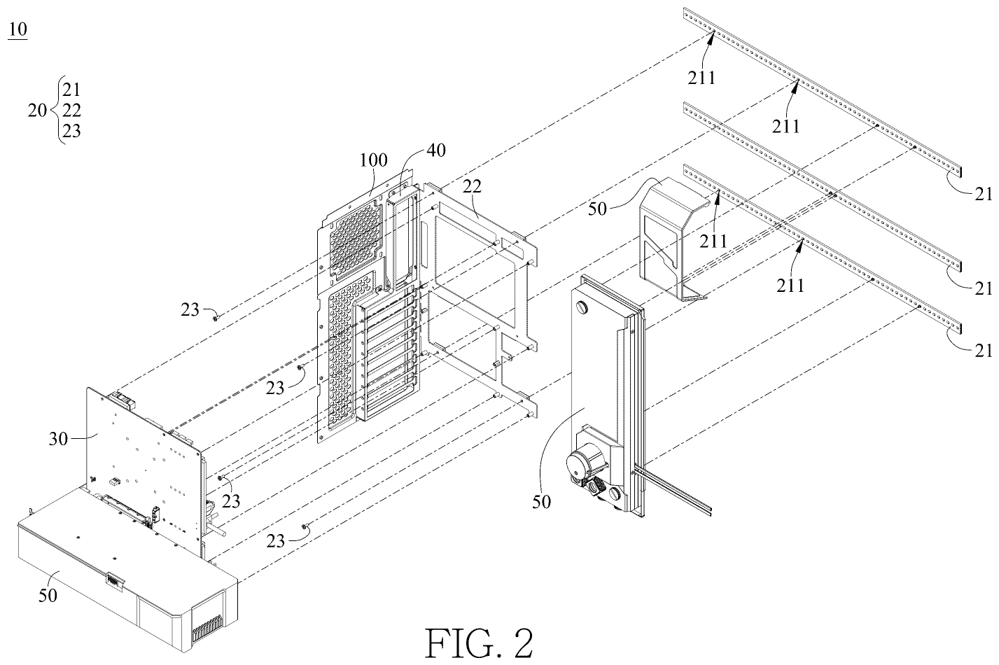

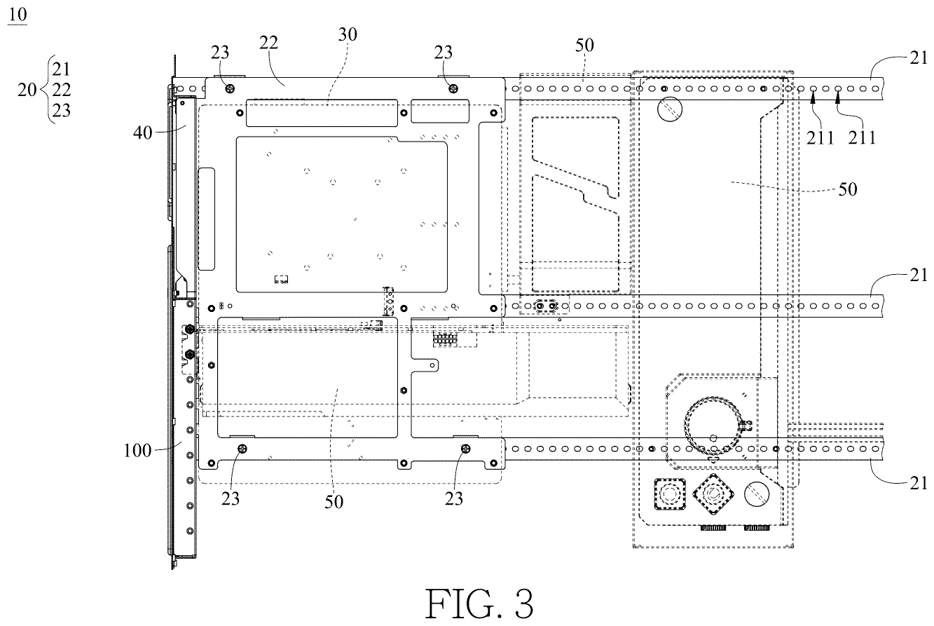

Referring to FIGS. 1-3. FIG. 1 is a perspective view of an electronic device in accordance with an embodiment of the present disclosure. FIG. 2 is an exploded view of the electronic device shown in FIG. 1. FIG. 3 is a top view of the electronic device shown in FIG. 1. As an example illustrated in FIG. 1, the electronic device 10 is disposed within a chassis (not shown) adjacent to a rear panel 100 of the chassis. However, the embodiment is not limited thereto. In other embodiments, the electronic device 10 can be disposed at other suitable locations.

In one embodiment, the electronic device 10 includes an installation assembly 20 and a motherboard 30. The installation assembly 20 further includes a plurality of mounting rods 21, a tray 22, and a plurality of second fastening structures 23. Each of the mounting rods 21 has a plurality of first fastening structures 211.

In one embodiment, the mounting rods 21 are arranged in parallel and horizontally. However, the embodiment is not limited thereto. In another embodiment, the mounting rods can be placed vertically.

In one embodiment, the first fastening structures 211 are threaded holes and are arranged along a longitudinal direction of the respective mounting rods 21. In an example, the spacing between any two adjacent first fastening structures 211 is 10 millimeters. However, the embodiment is not limited thereto. In other embodiments, the spacing may be adjusted depending on user needs and the configuration within the chassis.

In one embodiment, the second fastening structures 23 are screws and are disposed on the tray 22 such that they can be selectively threaded into the first fastening structures 211. Accordingly, the second fastening structures 23 pass through the tray 22 and are threaded into the first fastening structures 211 to secure the tray 22 to the mounting rods 21. When the second fastening structures 23 are disengaged from the first fastening structures 211, the tray 22 can be moved along the longitudinal direction of the mounting rods 21 to adjust its position relative thereto. Therefore, a user can adjust the position of the tray 22 on the mounting rods 21 based on personal preferences and the interior layout of the chassis. Additionally, the motherboard 30 is removably mounted to the tray 22.

In one embodiment, the electronic device 10 further includes a support bracket 40. For example, the support bracket 40 may be an I/O bracket. One side of the support bracket 40 is secured to the tray 22 with screws, and the other side of the support bracket 40 is secured to the rear panel 100 of the chassis with screws. Therefore, the tray 22 can be further securely mounted within the chassis.

In one embodiment, the electronic device 10 further includes a plurality of mounting components 50. For example, these mounting components 50 may include hard drives, graphics cards, cable shielding covers, radiators, or fans. The mounting components 50 may be removably mounted to at least some of the mounting rods 21 depending on the user's requirements and the interior layout of the chassis.

According to the embodiments above, the first fastening structures 211 are threaded holes, and the second fastening structures 23 are screws, such that the tray 22 is secured to the mounting rods 21 via threaded engagement between the second fastening structures 23 and the first fastening structures 211. However, the embodiment is not limited thereto. In other embodiments, the first and second fastening structures may be other suitable types of fasteners such as bolts and nuts, clips, or snap-fit connectors, allowing the tray to be secured to the mounting rods using alternate fastening methods.

According to the embodiments above, because the mounting rods 21 are arranged in parallel and each includes multiple first fastening structures 211 that are aligned along the longitudinal direction of the respective mounting rods 21, a user may install the tray 22 at any desired position on the mounting rods 21 based on personal preferences and the interior layout of the chassis. For example, the user may install the tray 22 at the rightmost end, the middle section, or the leftmost end of the mounting rods 21. Therefore, the flexibility and ease of tray installation are enhanced. Similarly, the mounting components 50 can also be installed at any position along the mounting rods 21 based on user's personal preference and the interior layout of the chassis, using the aforementioned structure. Accordingly, the mounting components 50 are more flexible and easier to install.

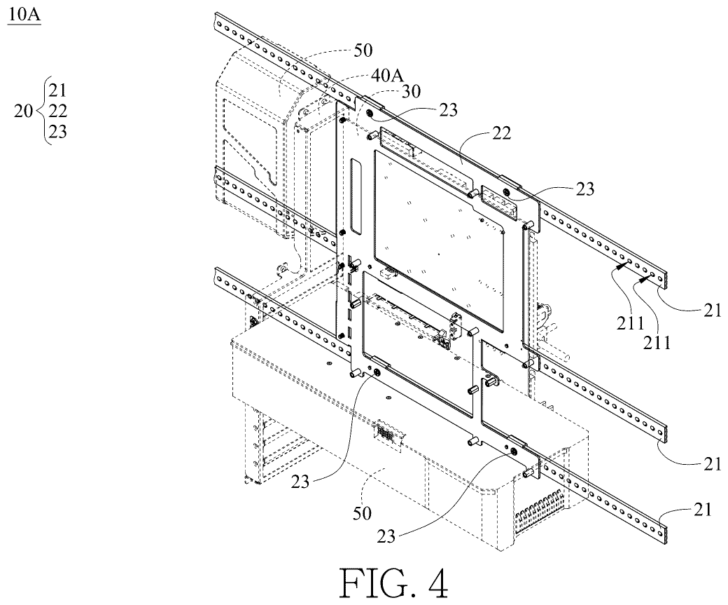

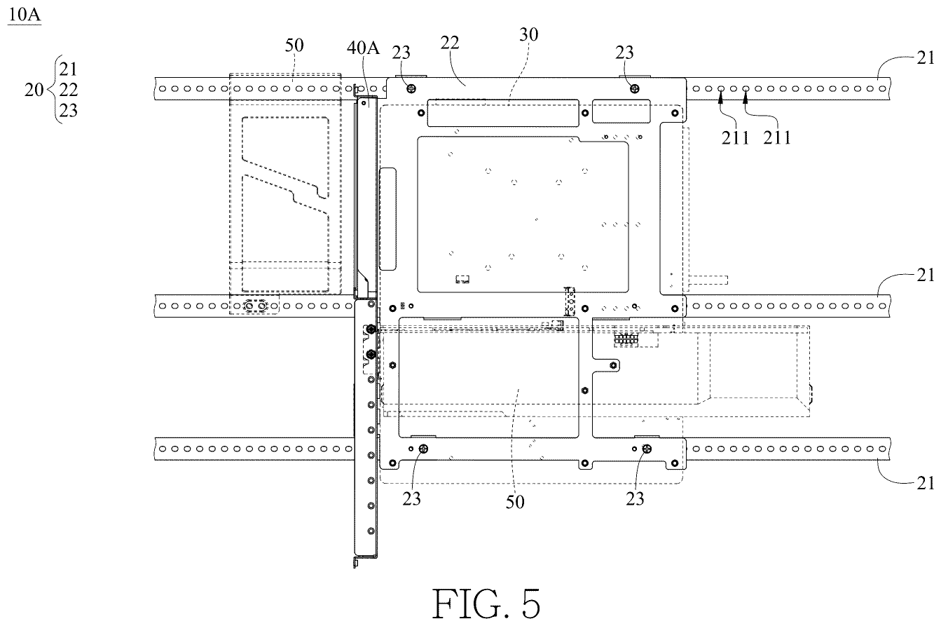

Referring to FIGS. 4-5. FIG. 4 is a perspective view of an electronic device in accordance with an embodiment of the present disclosure. FIG. 5 is a top view of the electronic device shown in FIG. 4. The electronic device 10A of FIG. 4 is similar to the electronic device 10 of FIG. 1 Therefore, the differences will be described below, while the similarities will not be repeated.

In one embodiment, the electronic device 10A is disposed within a chassis (not shown) at a location spaced apart from a rear panel (not shown) of the chassis. In other words, rather than being secured to the rear panel 100 of the chassis with screws, as shown in FIG. 1, the support bracket 40A of the electronic device 10A is distanced from the chassis rear panel. This configuration enables greater flexibility in component layout within the chassis, facilitating cable routing and airflow between the support bracket and the chassis rear panel. It also minimizes mechanical interference among adjacent components or structural elements, thereby improving the overall modularity and serviceability of the electronic device.

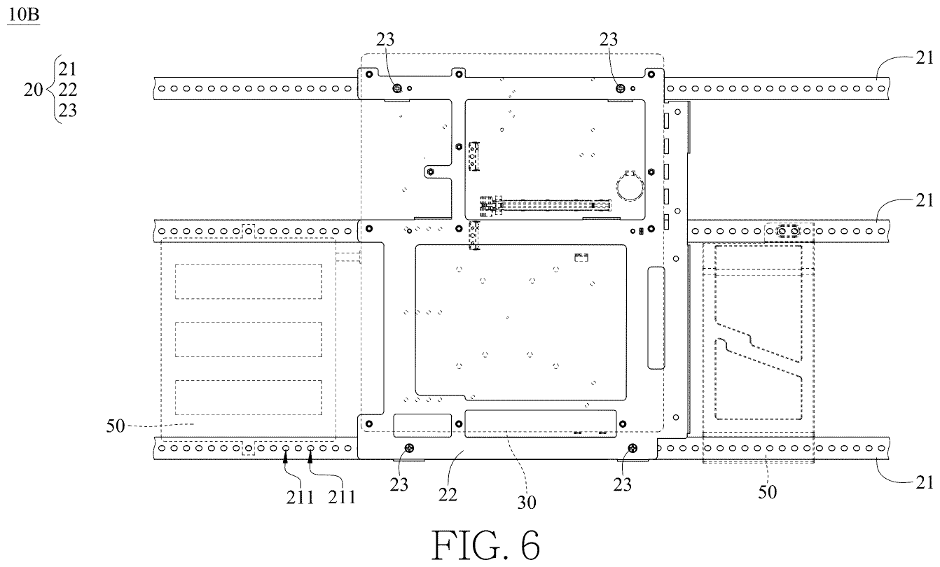

Referring to FIG. 6. FIG. 6 is a top view of an electronic device in accordance with an embodiment of the present disclosure. The electronic device 10B of FIG. 6 is similar to the electronic device 10 of FIG. 1. Therefore, the differences will be described below, while the similarities will not be repeated.

In one embodiment, the electronic device 10B allows adjustment of the positions of the mounting rods 21 within the chassis (not shown), as well as adjustment of the position of the tray 22 on the mounting rods 21, based on user requirements and the interior layout of the chassis. For example, the electronic device 10B is disposed within a chassis at a location away from the rear panel (not shown) of the chassis. The tray 22 and the motherboard 30 are disposed between the mounting components 50. Furthermore, the orientation of the electronic device 10B is approximately inverted in relation to the electronic device 10 of FIG. 1. This configuration allows for more flexible component placement while also optimizing space within the chassis. It also enhances airflow paths, improves thermal management options, and provides greater adaptability for various application-specific system layouts, such as systems that require component segregation, modular upgrades, or non-traditional installation orientations.

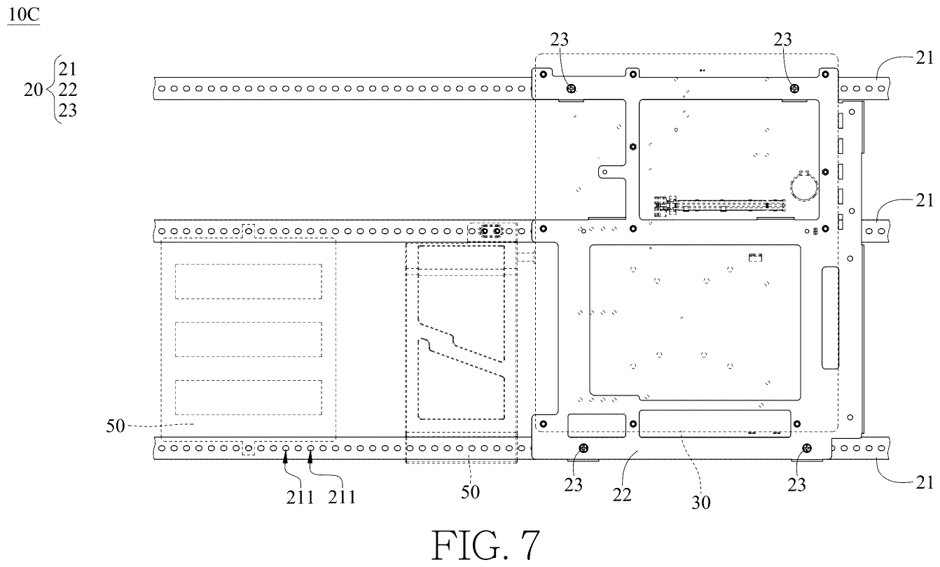

Referring to FIG. 7. FIG. 7 is a top view of an electronic device in accordance with an embodiment of the present disclosure. The electronic device 10C of FIG. 7 is similar to the electronic device 10 of FIG. 1. Therefore, the differences will be described below, while the similarities will not be repeated.

In one embodiment, the electronic device 10C allows adjustment of the positions of the mounting rods 21 within the chassis (not shown), as well as adjustment of the position of the tray 22 on the mounting rods 21, based on user requirements and the interior layout of the chassis. For example, the electronic device 10C is disposed within a chassis near the rear panel (not shown) of the chassis. The tray 22 and the motherboard 30 are disposed on one side of the mounting components 50. Additionally, the orientation of the electronic device 10C is approximately inverted in relation to the electronic device 10 of the first embodiment. This configuration helps maximize the use of vertical and lateral space within the chassis, allowing for alternative component stacking arrangements. It also supports system designs that require the motherboard to be closer to rear-panel interfaces or airflow areas. Further, this configuration provides greater design flexibility for customizing the component arrangement based on thermal, mechanical, or serviceability requirements.

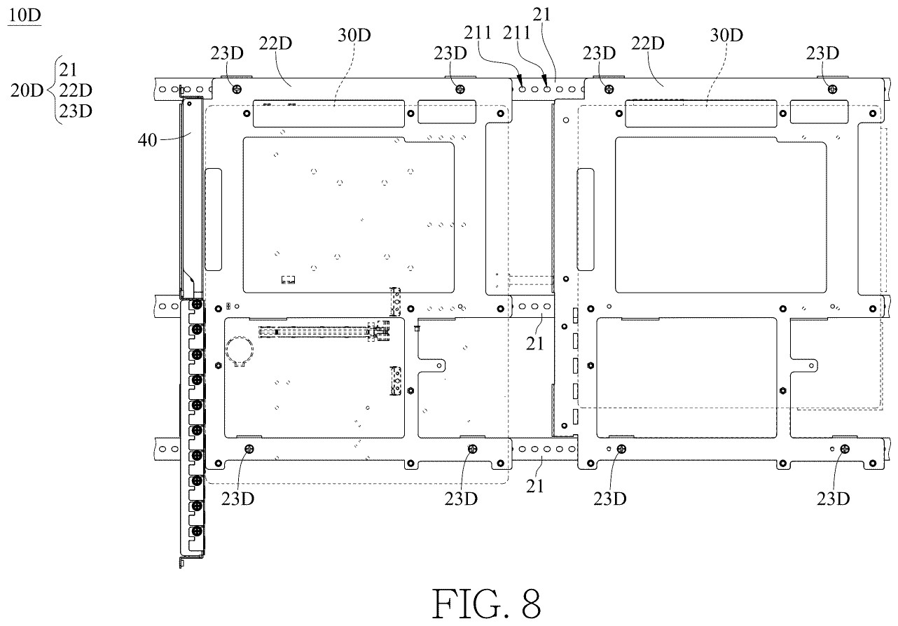

Referring to FIG. 8. FIG. 8 is a top view of an electronic device in accordance with an embodiment of the present disclosure. The electronic device 10D of FIG. 8 is similar to the electronic device 10 of FIG. 1. Therefore, the differences will be described below, while the similarities will not be repeated.

In one embodiment, the electronic device 10D may optionally include additional trays 22D and motherboards 30D based on user requirements. For example, the number of trays 22D and the number of motherboards 30D are two each. However, the embodiment is not limited thereto. In other embodiments, the number of trays and the number of motherboards may each be three or more.

In one embodiment, the two trays 22D are detachably secured to the mounting rods 21 and are positioned adjacently. The two motherboards 30D are respectively detachably mounted to the two trays 22D. This configuration enhances system scalability, space utilization, and flexibility for maintenance or upgrades.

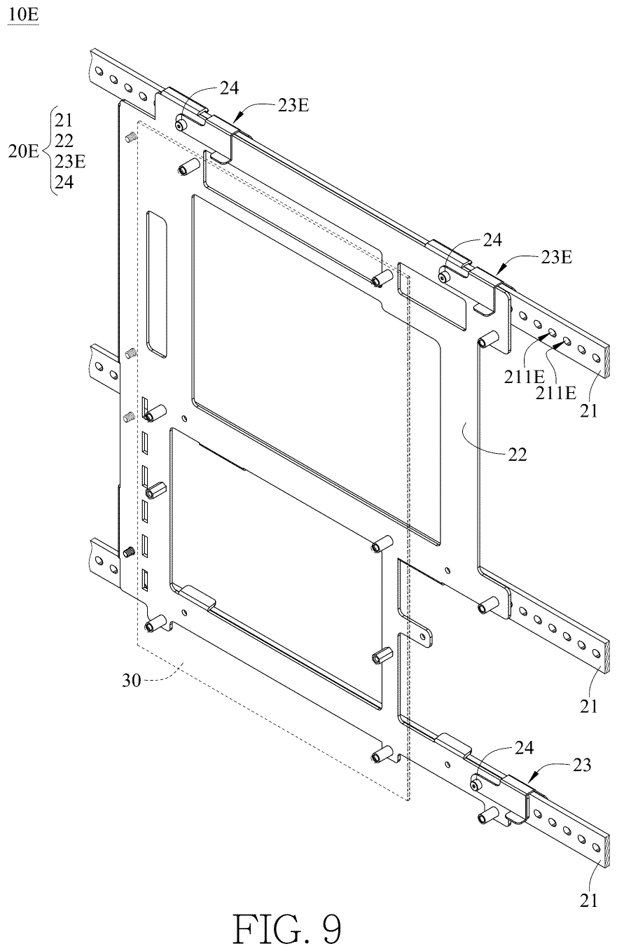

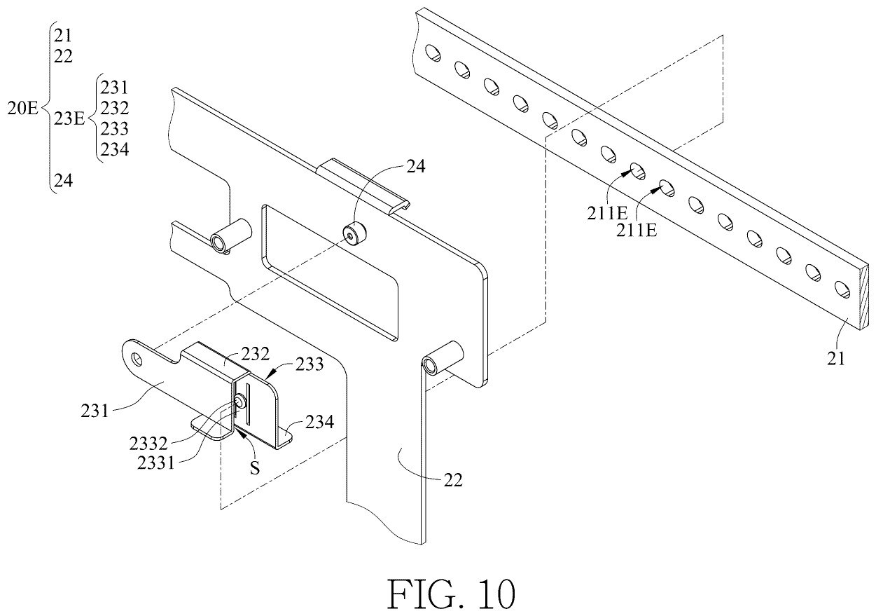

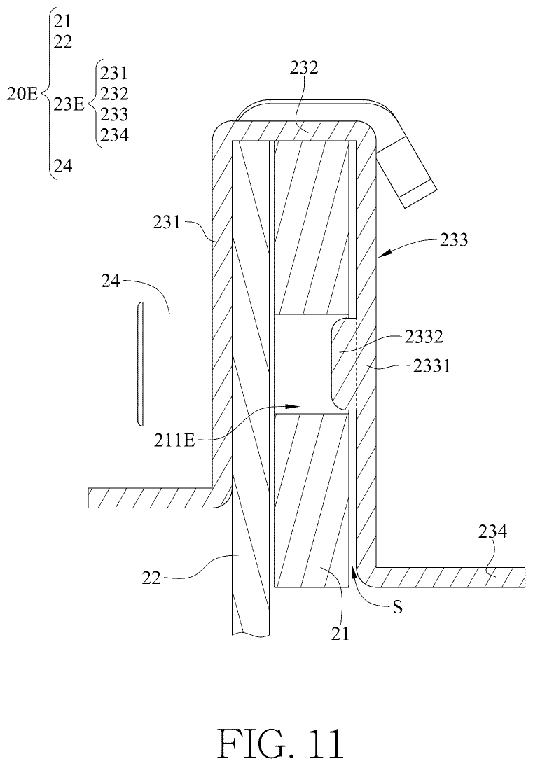

Referring to FIGS. 9-11. FIG. 9 is a perspective view of an electronic device in accordance with an embodiment of the present disclosure. FIG. 10 is a partially enlarged exploded view of the electronic device shown in FIG. 9, with the motherboard omitted. FIG. 11 is a partially enlarged cross-sectional view of the electronic device shown in FIG. 9, with the motherboard omitted.

In one embodiment, the electronic device 10E includes an installation assembly 20E and a motherboard 30. The installation assembly 20E includes multiple mounting rods 21, a tray 22, multiple second fixing structures 23E, and multiple pivot members 24. Each of the mounting rods 21 has multiple first fixing structures 211E. For example, the first fixing structures 211E are latch holes, and the second fixing structures 23E are flexible latch members. The tray 22 is detachably secured to the mounting rods 21, and the motherboard 30 is detachably secured to the tray 22. One side of each second fixing structure 23E is rotatably disposed on the tray 22.

In one embodiment, each second fixing structure 23E includes a first plate 231, a second plate 232, a third plate 233, and a fourth plate 234. A first side of the first plate 231 is pivotally connected to the tray 22 via a pivot member 24. Two sides of the second plate 232 on the side are respectively connected to a second side of the first plate 231 and to the third plate 233, such that the first plate 231, second plate 232, and third plate 233 together define an assembly slot S.

In one embodiment, the third plate 233 includes an elastic arm portion 2331 and a second latch structure 2332. For example, the second latch structure 2332 is a latch protrusion that complements the first fixing structure 211E. The second latch structure 2332 is located on the elastic arm portion 2331 within the assembly slot S, i.e., it protrudes toward the first plate 231. At least one of the mounting rods 21 is partially positioned within the assembly slots S of the second fixing structures 23E, allowing the second latch structures 2332 to selectively engage with the first fixing structures 211E.

In one embodiment, the fourth plate 234 is connected to the side of the third plate 233, which is away from the second plate 232 and protrudes in a direction away from the second latch structure 2332. The fourth plate 234 is user-controlled, enabling the rotation of the second fixing structure 23E or allowing it to be pulled to disengage the second latch structure 2332 from the first fixing structure 211E.

According to the embodiment, because the tray 22 of the electronic device 10E is provided with the second fixing structures 23E as flexible latch members, the user only needs to rotate the second fixing structure 23E so that the second latch structure 2332 engages with the first fixing structure 211E on the mounting rod 21, securing the tray 22 to the mounting rods 21. This configuration enhances the ease of securing the tray 22.

According to the embodiment, the first fixing structures 211E are latch holes, and the second latch structures 2332 are latch protrusions, but the embodiment is not limited thereto. In other embodiments, the first and second latch structures may be reversed, i.e., the first latch structures may be latch protrusions, and the second latch structures may be latch holes.

According to the embodiment, the first side of the first plate 231 is pivotally connected to the tray 22 via a pivot member 24, but the embodiment is not limited thereto. In other embodiments, the first side of the first plate may also be rotatably connected to the tray via other suitable means, such as a hinge mechanism, an elastic joint, or an integrated flexible extension formed as part of the tray or the first plate.

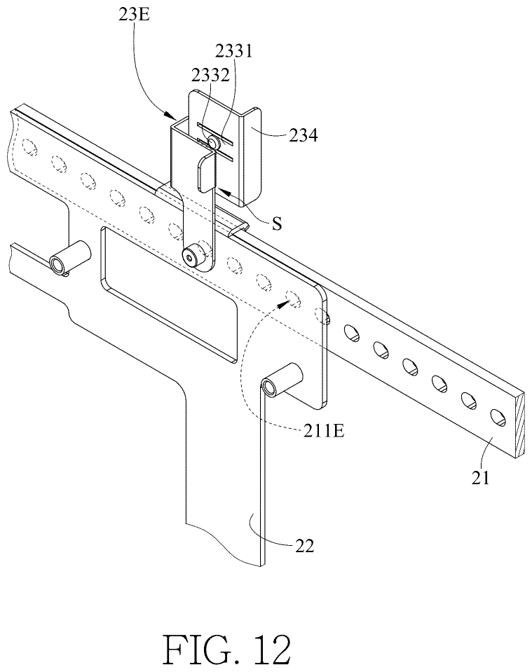

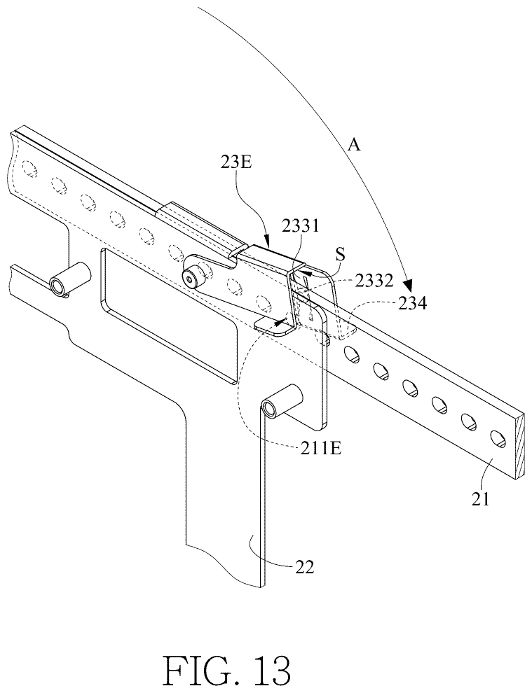

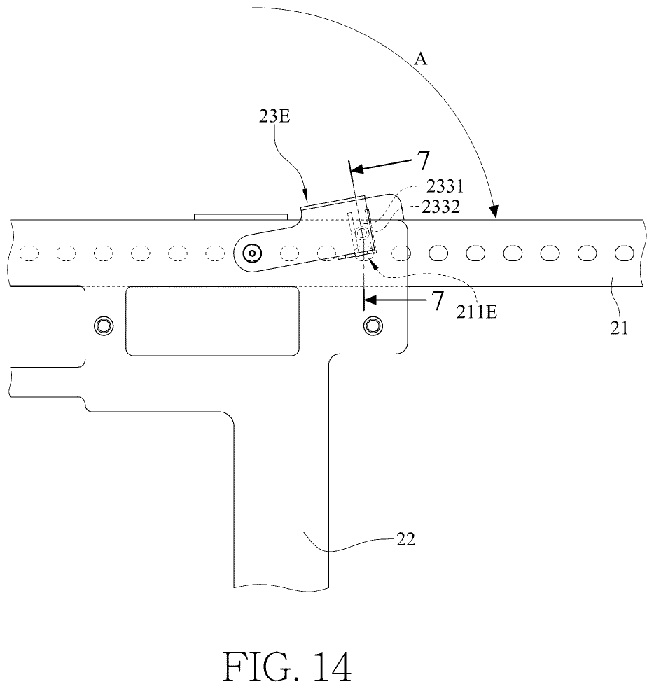

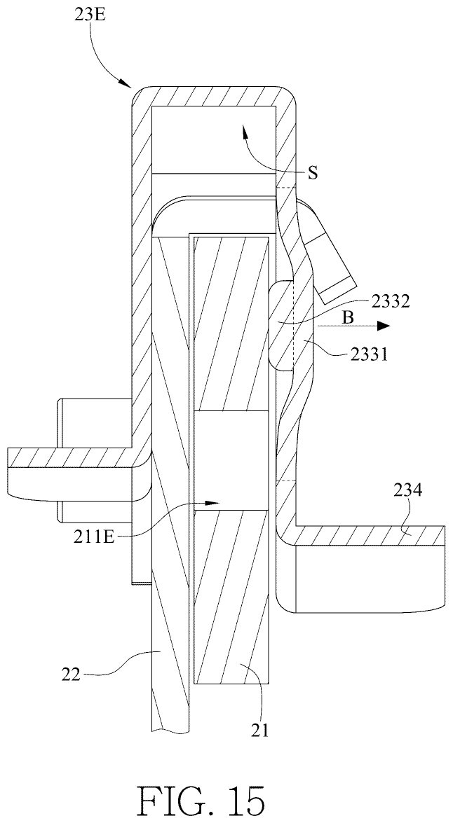

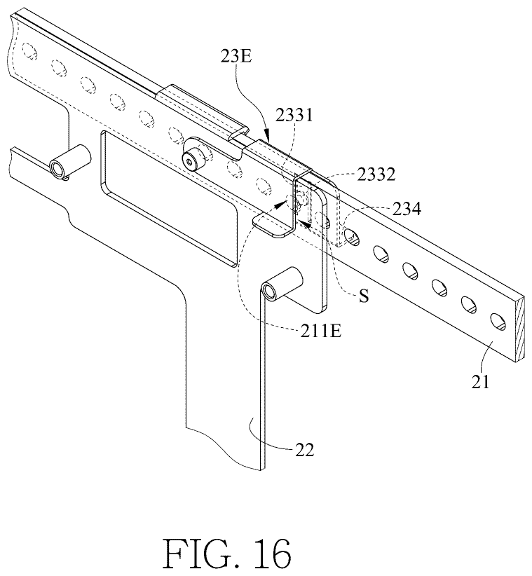

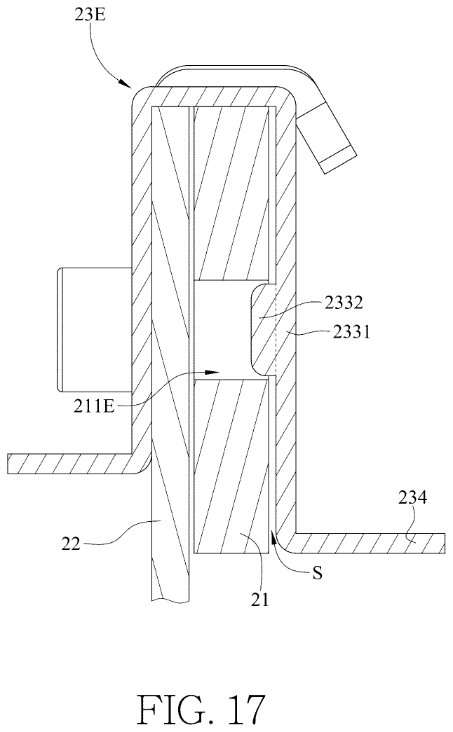

Referring to FIGS. 12-17. FIG. 12 is a partially enlarged perspective view of the electronic device shown in FIG. 9, illustrating a second fastening structure prior to engaging with a mounting rod. FIG. 13 is a partially enlarged perspective view of the electronic device shown in FIG. 9, illustrating the second fastening structure about to engage with the mounting rod. FIG. 14 is a partially enlarged side view of the portion shown in FIG. 13. FIG. 15 is a partially enlarged cross-sectional view taken along line 15-15 of FIG. 14. FIG. 16 is a partially enlarged perspective view of the electronic device shown in FIG. 9, illustrating the second fastening structure engaged with the mounting rod. FIG. 17 is a partially enlarged cross-sectional view of the portion shown in FIG. 16.

In one embodiment, when the user selects a position in the chassis (not shown) for mounting the motherboard 30 as shown in FIG. 9, the user first places the tray 22 on the mounting rods 21 as shown in FIG. 12, where the position of the tray 22 corresponds to the selected installation location. At this stage, the second fastening structure 23E has not yet latched onto the mounting rods 21. Next, as shown in FIGS. 13 to 15, the user rotates the second fastening structure 23E in direction A. At this point, the second latching structure 2332 interferes with the mounting rod 21, resulting in the elastic arm portion 2331 deforming in direction B and storing elastic energy. Subsequently, as shown in FIGS. 16 and 17, continued rotation of the second fastening structure 23E in direction A results in the mounting rod 21 being at least partially inserted into the assembly slot S. At this point, interference between the second latching structure 2332 and the mounting rod 21 is relieved, allowing the elastic arm portion 2331 to elastically return in the opposition direction of B; so, the second latching structure 2332 snaps into the first fastening structure 211E. Accordingly, the tray 22 is secured to the mounting rod 21 via the second fastening structure 23E, allowing the motherboard 30 to be mounted.

In one embodiment, when the user wants to change the mounting position of the tray 22 and the motherboard 30 as shown in FIG. 9, the user initially pulls the fourth plate 234 of the second fastening structure 23E in direction B to disengage the second latching structure 2332 from the first fastening structure 211E. Next, the user rotates the second fastening structure 23E in the reverse direction of A. Therefore, the tray 22 can be removed from the mounting rod 21, and the tray 22 and motherboard 30 can be repositioned as desired.

According to the present disclosure, because each of the parallel mounting rods has multiple first fastening structures arranged along the longitudinal direction of the rods, the user can mount the tray at any position on the mounting rods based on personal requirements and the interior layout of the chassis. For example, the user may choose to mount the tray at the far-right end, the middle, or the far-left end of the mounting rods. This enhances the flexibility and ease of tray installation.

Similarly, the mounting components can also be installed at any position on the mounting rods according to the user's requirements and the chassis layout by using the above-mentioned structure. This likewise enhances the flexibility and ease of mounting the components.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. Of course, the disclosed embodiments are merely exemplary embodiments and that various modifications can be made without departing from the spirit and scope of the disclosure. Further, it should be understood that various aspects of the embodiment are not mutually exclusive of each other and can be combined as desired by a person of ordinary skill in the art as a matter of design choices.

The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

What is claimed is:

1. An electronic device, comprising:
an installation assembly, including:
a plurality of mounting rods, each having a plurality of first fastening structures, the mounting rods being parallel to one another, and the first fastening structures being arranged along longitudinal directions of the mounting rods, respectively;
a tray;
a plurality of second fastening structures configured to be disposed on the tray and selectively fastened to the first fastening structures, such that when the first and the second fastening structures are disengaged, the tray is movable along a longitudinal direction of the mounting rods to adjust a positional relationship therebetween; and
a motherboard detachably mounted to the tray.

2. The electronic device of claim 1, wherein each of the first fastening structures includes a threaded hole, and each of the second fastening structures includes a screw configured to pass through the tray and be selectively threaded into the first fastening structure.

3. The electronic device of claim 1, wherein each of the first fastening structures includes a latch hole, each of the second fastening structures includes a flexible latch member, and one side of the second fastening structure is rotatably mounted to the tray.

4. The electronic device of claim 3, wherein each of the second fastening structures includes a first plate, a second plate, and a third plate, a first side of the first plate being rotatably mounted to the tray, two sides of the second plate on the side being respectively connected to a second side of the first plate and the third plate, thereby forming an assembly slot with the first, second, and third plate collectively.

5. The electronic device of claim 4, wherein the third plate includes an elastic arm portion and a latch protrusion, the latch protrusion being located on the elastic arm portion adjacent to the assembly slot, and the mounting rods being configured to be at least partially received within the assembly slot, thereby allowing the latch protrusion to engage with the first fastening structures.

6. The electronic device of claim 5, wherein the latch protrusion protrudes from the third plate towards the first plate.

7. The electronic device of claim 5, wherein each of the second fastening structures includes a fourth plate, the fourth plate being connected to a side of the third plate opposite the second plate and protruding in a direction away from the latch protrusion.

8. The electronic device of claim 4, further comprising a plurality of pivot members, wherein the first side of the first plate is pivotally mounted to the tray via a respective pivot member.

9. The electronic device of claim 1, further comprising at least one mounting component removably mounted to at least a portion of the mounting rods.

10. The electronic device of claim 1, wherein a spacing between any two adjacent ones of the first fastening structures is 10 millimeters.

11. An installation assembly configured for mounting a motherboard, the installation assembly comprising:
a plurality of mounting rods, each having a plurality of first fastening structures, the mounting rods being parallel to one another, and the first fastening structures being arranged along longitudinal directions of the mounting rods, respectively;
a tray configured to receive the motherboard; and
a plurality of second fastening structures configured to be disposed on the tray and selectively fastened to the first fastening structures, allowing the tray to move along a longitudinal direction of the mounting rods to adjust a positional relationship therebetween when the first fastening structures and the second fastening structures are disengaged.

12. The installation assembly of claim 11, wherein each of the first fastening structures includes a threaded hole, and each of the second fastening structures includes a screw being configured to pass through the tray and be selectively threaded into the first fastening structure.

13. The installation assembly of claim 11, wherein each of the first fastening structures includes a latch hole, each of the second fastening structures includes a flexible latch member, and one side of the second fastening structure is rotatably mounted to the tray.

14. The installation assembly of claim 13, wherein each of the second fastening structures includes a first plate, a second plate, and a third plate, a first side of the first plate being rotatably mounted to the tray, two sides of the second plate on the side being respectively connected to a second side of the first plate and the third plate thereby forming an assembly slot with the first plate, second plate, and third plate collectively.

15. The installation assembly of claim 14, wherein the third plate includes an elastic arm portion and a latch protrusion, the latch protrusion being located on the elastic arm portion adjacent to the assembly slot, and the mounting rods being configured to be at least partially received within the assembly slot, allowing the latch protrusion to engage with the first fastening structures.

16. The installation assembly of claim 15, wherein the latch protrusion protrudes from the third plate towards the first plate.

17. The installation assembly of claim 15, wherein each of the second fastening structures includes a fourth plate, the fourth plate being connected to a side of the third plate opposite the second plate and protruding in a direction away from the latch protrusion.

18. The installation assembly of claim 14, further comprising a plurality of pivot members, wherein the first side of the first plate is pivotally mounted to the tray via a respective pivot member.

19. The installation assembly of claim 11, further comprising at least one mounting component removably mounted to at least a portion of the mounting rods.

20. The installation assembly of claim 11, wherein a spacing between any two adjacent ones of the first fastening structures is 10 millimeters.
